(19) United States
(12) Patent Application Publication
(10) Pub. No.: US 2026/0189243 A1
(43) Pub. Date: Jul. 2, 2026

(54) Analog-To-Digital Converter Integrated Circuit Having Function Of Two Closest Error Correction

(71) Applicant: Apogee Semiconductor, Inc., Plano, TX (US)

(72) Inventor: David A. Grant, Edinburgh (GB)

(21) Appl. No.: 19/548,914

(22) Filed: Feb. 24, 2026

Related U.S. Application Data
(63) Continuation-in-part of application No. 18/759,812, filed on Jun. 29, 2024.

(51) Int. Cl. H03M 1/12

(52) U.S. Cl. CPC H03M 1/1205

(57) ABSTRACT

A “rad hard” or “rad tolerant” analog-to-digital converter (ADC) integrated circuit includes a pair of input voltage terminals, three ADCs, a function of the two closest (FOTC) circuit, and an output port. Each of the three ADCs performs an analog-to-digital conversion and outputs a value indicative of the voltage between the pair of input voltage terminals. The FOTC circuit determines which of the three ADC output values are the two numerically closest values, and determines and outputs a FOTC value. The FOTC value is a multi-bit digital value taken from the group consisting of: one of the two numerically closest ADC output values, the sum of the two numerically closest ADC output values, and the average of the two numerically closest ADC output values. The FOTC value is output from the integrated circuit via the output port

### CROSS REFERENCE TO RELATED APPLICATION

This application is a continuation of, and claims the benefit under 35 U.S.C. § 120 from, nonprovisional U.S. patent application Ser. No. 18/759,812, entitled “Processor Employing Instruction That Performs A Sum Of Two Closest Operation,” filed on Jun. 29, 2024. The subject matter of the foregoing document is incorporated herein by reference.

### GOVERNMENT SUPPORT

This invention was made with Government support under Contract No. 80LARC20C0005 awarded by the National Aeronautics and Space Administration (NASA). The Government has certain rights in the invention.

### TECHNICAL FIELD

This disclosure relates to reliable and fault tolerant so-called “rad-hard” and/or “rad-tolerant” analog-to-digital converters (ADCs) that are suitable for use in applications (such as aerospace applications) where circuit operation may be adversely affected by unwanted incident radiation.

### BACKGROUND INFORMATION

In electronic systems intended to operate with high reliability in harsh environments including high radiation environments, the principle of triple modular redundancy is sometimes employed. A high energy particle may pass through a part of the electronic circuitry such that a state change occurs in a bit of the digital information stored in the circuitry. Such an erroneous change of state may be referred to as a single-event effect or a single-event upset. In an application of the triple modular redundancy principle, a signal path which could be corrupted by such a single-event upset is replicated to three or more replicated signal paths. The outputs of the replicated signal paths may be passed through a majority voting system, which resolves differences between the multiple replicated paths, and outputs the result of the majority vote.

### SUMMARY

In one novel aspect, a “rad-hard” or “rad-tolerant” integrated circuit comprises a first terminal AVIN, a second terminal VREF, a first analog-to-digital converter (ADC) circuit, a second ADC circuit, a third ADC circuit, and a function of two closest (FOTC) circuit. An analog voltage to be sensed (for example, a analog voltage signal in a voltage range between zero and one volts) is present between the first and second terminals. The first ADC circuit senses the voltage between the first and second terminals, and outputs a multi-bit digital value U that is an analog-to-digital conversion value indicative of the magnitude of the voltage. The second ADC circuit senses the voltage between the first and second terminals, and outputs a multi-bit digital value M that is an analog-to-digital conversion value indicative of the magnitude of the voltage. The third ADC circuit senses the voltage between the first and second terminals, and outputs a multi-bit digital value D that is an analog-to-digital conversion value indicative of the magnitude of the voltage. The three ADC circuits are of identical construction. The three ADC circuits are controlled and synchronized to perform their respective analog-to-digital conversions on the same voltage signal at the same time, or at substantially the same time.

The FOTC circuit receives the value U from the first ADC circuit, the value M from the second ADC circuit, and the value D from the third ADC circuit, and from these three values determines which two of the values are the two numerically closest values. In a first embodiment, the FOTC circuit generates a multi-bit digital FOTC value that is a selected one of the two numerically closest values. This selected one may be selected to be the one that is numerically between the other two values U, M and D. In a second embodiment, the FOTC circuit generates a multi-bit digital FOTC value that is the sum of the two numerically closest values. In a third embodiment, the FOTC circuit generates a multi-bit digital FOTC value that is the average of the two numerically closest values. In a preferred embodiment, the FOTC circuit comprises only combinatorial digital logic elements, and includes no sequential digital logic element.

In one embodiment, the integrated circuit further comprises a multi-terminal parallel digital output port. This port may, for example, include thirteen integrated circuit package terminals, and an associated data valid integrated circuit package terminal. The FOTC value is output (in parallel form) from the integrated circuit via the multi-terminal parallel digital output port. The integrated circuit is a packaged integrated circuit that includes an integrated circuit die as well as an integrated circuit package. The term “integrated circuit” may refer to an integrated circuit die, and/or to a packaged integrated circuit, depending on the context of usage of the term.

In another embodiment, the integrated circuit further comprises a serial interface circuit and four-terminal port. The serial interface circuit and port may, for example, be a Serial Peripheral Interface (SPI) interface. The FOTC value is output from the integrated circuit via the serial interface port. In one example, the FOTC value is output in serial form multiple times (for example, three times in succession) from this serial interface port.

In one embodiment, the manner in which the integrated circuit outputs the FOTC value is configurable. The integrated circuit includes a configuration register. The content of the configuration register determines how the integrated circuit outputs the FOTC value. The content of this configuration register can be loaded by circuitry outside the integrated circuit via the serial interface circuit and port. In addition to the configuration register, the integrated circuit has a plurality of externally-accessible configuration integrated circuit package terminals. In one configuration mode, the voltages present on these terminals determine the particular FOTC function used by the FOTC circuit to generate the FOTC value, and also determine how the integrated circuit outputs the FOTC value, and override the content of the configuration register, thereby allowing the FOTC functionality of the integrated circuit to be used without having to be configured through a serial interface port. Accordingly, in a first configuration mode the content of the configuration register determines FOTC functionality, whereas in a second configuration mode the voltages on the configuration integrated circuit package terminals determine FOTC functionality.

The integrated circuit, by outputting the FOTC value, performs a kind of error correction function. There are imperfections in an analog-to-digital conversion process, such that even in a no-fault situation, multiple identical ADC circuits performing analog-to-digital conversions on the very same input voltage may generate ADC output values that differ from one another by more than one bit. ADC circuits operating in a no-fault situation may output ADC values that differ from each other, for example, due to noise, linearity errors, offset errors, gain errors, and other reasons. In the case of a single-event upset error due to a high energy particle, where that error is manifest in one of the ADC output values, it is not always possible to detect the erroneous ADC output by simply identifying the one ADC output value that is different from the other two ADC output values, and that is because that other two ADC output values may differ from each other. Accordingly, the preferred FOTC function is the function of the “sum of the two closest” ADC output values U, M and D, because this sum retains information of both of the two closest ADC output values even in the case where those two closest ADC output value differ from one another.

In accordance with a novel method, in a step (a) a first ADC circuit generates a first multi-bit digital value U, where the value U is a value indicative of a voltage between a first node and a second node. In a step (b), a second ADC circuit generates a second multi-bit digital value M, where the value M is indicative of the voltage between the first node and the second node. In a step (c), a third ADC circuit generates a third multi-bit digital value D, where the value D is indicative of the voltage between the first node and the second node. A step (d) involves a function of two closest (FOTC) circuit determining which two of the values U, M and D are the two numerically closest values. A step (e) involves the FOTC circuit determining a “function of the two closest” (FOTC) value, where the FOTC value is taken from the group consisting of: one of the two numerically closest values determined in step (d), the sum of the two numerically closest values determined in step (d), and the average of the two numerically closest values determined in step (d). Neither step (d) nor step (e) is performed by a digital processor that fetches, decodes and executes instructions. In one example of the method, the FOTC circuit, the first ADC circuit, the second ADC circuit, and the third ADC circuit are all parts of the same integrated circuit. The first node is a node that includes a first integrated circuit package terminal AVIN. The second node is a node that includes a second integrated circuit package terminal VREF. In one example of the method, the method further includes a step (f) of outputting the FOTC value from the integrated circuit such as for example via a multi-terminal parallel digital output port of the integrated circuit, or via a serial interface port of the integrated circuit.

Further details and embodiments and methods and techniques are described in the detailed description below. This summary does not purport to define the invention. The invention is defined by the claims.

### BRIEF DESCRIPTION OF THE DRAWINGS

The accompanying drawings, where like numerals indicate like components, illustrate embodiments of the invention.

FIG. 1 is a simplified circuit diagram of a system 1 that includes a rad-hard analog-to-digital transducer integrated circuit 2.

FIG. 2 is a Verilog hardware description language description of one example of the FOTC circuit 12 of the integrated circuit 2 of FIG. 1.

### DETAILED DESCRIPTION

Reference will now be made in detail to embodiments of the invention, examples of which are illustrated in the accompanying drawings.

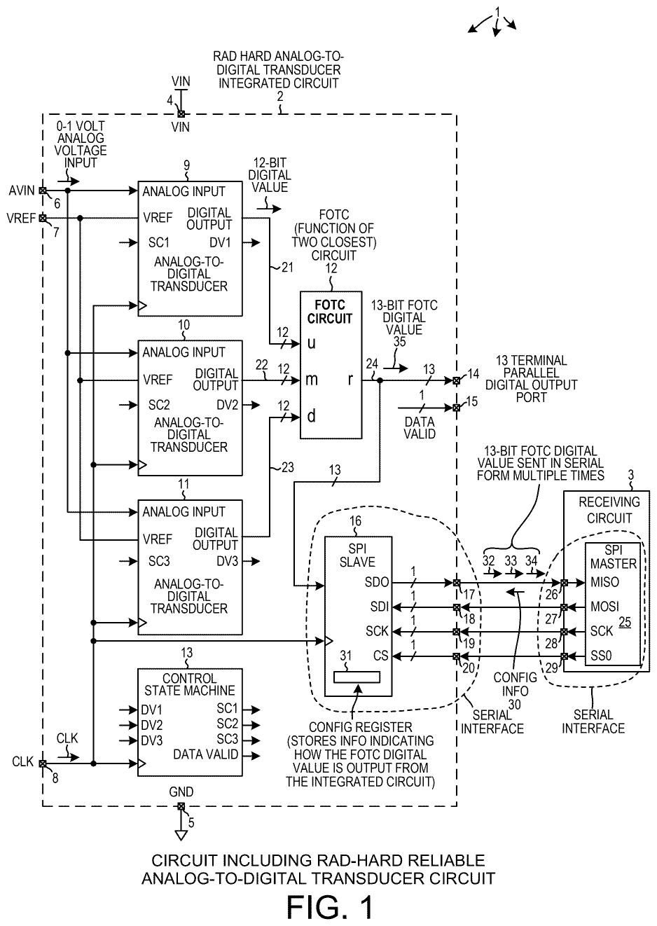

FIG. 1 is a simplified circuit diagram of a system 1 that includes a radiation hardened (“rad-hard”) or radiation tolerant (“rad-tolerant”) analog-to-digital transducer integrated circuit 2 and a receiving circuit 3. In the specific illustrated case, the transducer type is an analog-to-digital converter (ADC) where the analog quantity being measured and converted into a multi-bit digital value is an analog voltage. More specifically, the ADC is a resistor-capacitor hybrid successive approximation register (SAR) ADC. In other examples, each of the ADCs is an ADC of another type such as a delta-sigma ADC (also called a sigma-delta ADC). In other examples, the analog-to-digital transducers may be of a type that converts another analog quantity (other than an analog voltage) into a multi-bit digital conversion value.

Integrated circuit 2 includes a power input terminal VIN 4, a ground terminal GND 5, an analog sense voltage AVIN input terminal 6, a voltage reference VREF input terminal 7, a clock signal input terminal CLK 8, a first ADC 9, a second ADC 10, a third ADC 11, a function of two closest (FOTC) circuit 12, a control digital state machine 13, a parallel digital output port 14 of thirteen output terminals, a data valid output terminal 15, a serial interface circuit 16, and four terminals 17-20 of a serial interface port. In the illustration of FIG. 1, the integrated circuit 2 is actually a packaged integrated circuit, with a terminal symbol representing both a bond pad of the integrated circuit die as well as the corresponding package terminal, and any necessary connection or bond wire between the two. The packaged integrated circuit includes an integrated circuit package and an integrated circuit die.

An analog voltage to be sensed (for example, a analog voltage signal in a voltage range between zero and one volts) is present between the voltage sense AVIN input terminal 6 and the VREF input terminal 7. The first ADC 9 senses the voltage between the sense AVIN input terminal 6 and the VREF input terminal 7, and outputs a 12-bit multi-bit digital value U that is an analog-to-digital conversion value indicative of the magnitude of the voltage. The value U is supplied in parallel form via a set of conductors 21 to a U value input of the FOTC circuit 12.

The second ADC 10 senses the voltage between the sense AVIN input terminal 6 and the VREF input terminal 7, and outputs a 12-bit multi-bit digital value M that is an analog-to-digital conversion value indicative of the magnitude of the voltage. The value M is supplied in parallel form via a set of conductors 22 to an M value input of the FOTC circuit 12.

The third ADC 11 senses the voltage between the sense AVIN input terminal 6 and the VREF input terminal 7, and outputs a 12-bit multi-bit digital value D that is an analog-to-digital conversion value indicative of the magnitude of the voltage. The value D is supplied in parallel form via a set of conductors 23 to a D value input of the FOTC circuit 12.

In the presently described embodiment, each of the ADCs 9, 10, and 11 receives a start convert input signal from the control state machine 13. SC1 is the start convert signal for the first ADC 9. SC2 is the start convert signal for the second ADC 10. SC3 is the start convert signal for the third ADC 11. The three ADCs are controlled so that each ADC performs an analog-to-digital conversion on the same input sense voltage. There may be additional sample and hold circuitry, additional buffer circuitry, and additional analog multiplexer circuitry provided between the input terminals 6 and 7 and the three ADCs 9, 10, 11 to facilitate the three ADC performing their respective conversions on the same input voltage.

In one example, the three ADCs 9, 10 and 11 are of identical layout and circuit construction. They perform their analog-to-digital conversions at the same time, and they output their respective output values to the FOTC circuit at the same time. In the illustrated example, each ADC outputs a single-bit data valid output signal. Signal DV1 is the data valid output signal from the first ADC 9. Signal DV2 is the data valid output signal from the second ADC 10. Signal DV3 is the data valid output signal from the third ADC 11. The control state machine 13 uses the three data valid signals DV1, DV2 and DV3 to assure that all three ADCs have output their respective analog-to-digital conversion values to the FOTC circuit 12 in adequate time for the FOTC circuit 12 to be outputting a settled and valid 13-bit FOTC value 35 before the control state machine 13 will assert the data valid signal that is output from the integrated circuit 2 via DATA VALID terminal 15.

The FOTC circuit 12 receives the three multi-bit digital values U, M and D from the ADCs. FOTC circuit 12 determines the absolute numerical difference between value U and value M, the absolute numerical difference between value M and value D, and the absolute numerical difference between value U and value D. From these three absolute difference values, the FOTC circuit 12 determines which of the two values U, M and D are the two numerically closest values. Based on this, the FOTC circuit 12 outputs a multi-bit FOTC value onto a set of conductors 24. In a first example, the FOTC value 35 is one of the two numerically closest values. In a second example, the FOTC value 35 is the sum of the two numerically closest values. In a third example, the FOTC value 35 is the average of the two numerically closest values.

In a preferred embodiment, the FOTC circuit 12 is an amount of combinatorial digital logic that includes no sequential digital logic element, and that is hardwired so that it will only output (as the FOTC value) the sum of the two numerically closest values as a single 13-bit digital value onto the set of conductors 24. The FOTC circuit 12 does not include a processor that executes instructions. The FOTC circuitry within the FOTC block 12 and the circuitry to terminals 14 and 15 of FIG. 1 is replicated three times in order to make the FOTC value output of the integrated circuit more resistant to single event radiation induced transients and errors.

The “sum of the two numerically closest” function handles the special case of there not being one and only one “closest” pair of values in one of multiple different ways. The term “sum of the two numerically closest” function as it is used here is a general term that describes an FOTC function that handles the special case in any of these ways. In one example, if the three ADC output values U, M and D happen to be such that the lowest and highest values are equidistant from the mid-value, and the three values U, M and D are all different values, then the FOTC circuit 12 outputs the FOTC value to be a value that is two times (twice) the mid-value. Stated another way, if the numerical difference between a first pair of the U, M and D values is equal to the numerical difference between a second pair of the U, M and D values, and if the third pair of the U, M and D values is numerically larger than the first and second pairs, and if the U, M and D values are three different values, then the FOTC value output by the FOTC circuit is a value that is two times (twice) the middle value, where the middle value is the value (of the U, M and D values) that is neither the largest of the U, M and D values nor is the smallest of the U, M and D values. In another example, the FOTC value output by the FOTC circuit in this special case is the sum of the largest of U, M and D and the smallest of U, M and D. In another example, in the special case of the two of the values U, M and D being the same and differing from the third value, the FOTC value output by the FOTC circuit is the sum of the two values that are the same.

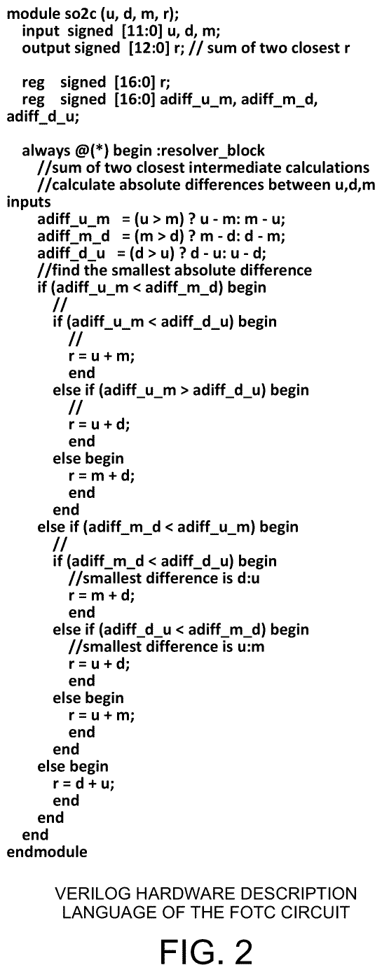

FIG. 2 is a Verilog hardware description language (HDL) description of one example of the FOTC circuit 12 of the integrated circuit 2 of FIG. 1, where the HDL code shows the algorithmic structure of the example FOTC circuit. The FOTC circuit may be realized as an amount of dedicated non-programmable combinatorial digital logic circuitry by describing the Boolean logic function of the FOTC circuit in a hardware description language such as Verilog, and then using commercially available hardware synthesis software tools to convert the Verilog description into combinatorial digital logic hardware circuitry that implements the described logic function as is known in the art. The FOTC value is the sum of the two numerically closest values in cases in which there is one and only one set of two values that are the closest. The FOTC value is the sum of the value M and the value D in a case in which the difference between the value D and the value U equals the difference between the value M and the value U, whereas the FOTC value is the sum of the value D and the value U in a case in which the difference between the value D and the value M equals the difference between the value U and the value M, whereas the FOTC value is the sum of the value U and the value M in the case in which the difference between the value U and the value D equals the difference between the value M and the value D.

The FOTC value 35 is output from the integrated circuit 2 via the thirteen terminals of the parallel digital output port 14. The data valid signal on the terminal 15 may be provided to indicate when the FOTC value is valid on the port 14 and is not transitioning, and can be read. The data valid signal on terminal 15 is typically made to transition with appropriate setup and hold times with respect to the clock signal CLK. In the specific embodiment illustrated in FIG. 1, there is no sequential logic or registering of data in the data path through the FOTC circuit 12, and from the FOTC circuit 12 to the parallel digital output port 14. The absence of sequential logic and registering in this data path makes the integrated circuit less susceptible to radiation-caused single event upset events.

From the outside, the “rad-hard” or “rad-tolerant” integrated circuit 2 can be made to look perform much like an ordinary ADC integrated circuit, but one that simply does not make mistakes due to radiation that would otherwise cause single event upset errors. In one embodiment in which the integrated circuit 2 looks to an end user from the outside the package like an ordinary packaged ADC integrated circuit, the FOTC circuit 12 includes no processor that fetches and executes instructions.

The FOTC value 35 is also supplied to the serial interface circuit 16, which in the present embodiment is an SPI bus (Serial Peripheral Interface bus) interface slave circuit. A SPI bus interface master circuit 25 of the receiving circuit 3 uses four terminals 26-29 to communicate with the SPI slave 16 of the integrated circuit 2. The SPI master 25 initially writes configuration information 30 into the integrated circuit 2 so as to load the configuration information into a configuration register 31. This configuration information 30 determines how the integrated circuit 2 will output the FOTC value. The configuration information may configure I/O terminals of the integrated circuit 2 to have different functions depending on how the FOTC value is configured to be output from the integrated circuit 2. The configuration information may also configure the particular FOTC function used by the FOTC circuit 12 in the generation of the FOTC value. In the present example, the FOTC value is output from the integrated circuit 2 serially three times as values 32, 33 and 34. The receiving circuit 3 knows that it should be receiving the same FOTC value three times, so should one of the three incoming FOTC values be corrupted and differ from the other two, the receiving circuit 3 can detect this single failure and use the FOTC value of the other two presumably uncorrupted FOTC values to be the correct FOTC value.

In one embodiment, the integrated circuit 2 has an additional a plurality of externally-accessible configuration integrated circuit package terminals (not illustrated). In one configuration mode, the voltages supplied to these terminals from outside the integrated circuit 2 determine the particular FOTC function the FOTC circuit uses to generate FOTC value, and also determine how the integrated circuit 2 outputs the FOTC value, and override the content of the configuration register, thereby allowing the FOTC functionality of the integrated circuit 2 to be configured and used without the FOTC functionality having to be configured in another way such as through a serial interface port.

Although an example is described here in which the FOTC circuit is configurable to generate FOTC values using a selectable one of multiple FOTC functions, in most implementations of the integrated circuit 2 the FOTC circuit only implements one fixed and predetermined FOTC function to generate FOTC values. The FOTC circuit is not programmable or configurable to change the FOTC function.

Although in the illustration of FIG. 1. there is only one input voltage terminal AVIN pictured from which an input voltage could be supplied to the ADCs 9-11 for measurement, the integrated circuit 2 may have multiple such input voltage terminals. In a case in which there are multiple such input voltage terminals, there is an analog multiplexer circuit. The analog multiplexer circuit has multiple analog inputs and input leads, a single analog output and output lead, and a plurality of select inputs and leads. Each respective one of the analog input leads of the multiplexer circuit is coupled to a corresponding one of the input voltage terminals. The analog output lead of the analog multiplexer circuit is coupled to the analog inputs of the three ADCs 9-11. The select inputs and input leads of the analog multiplexer circuit are coupled by corresponding conductors to the control state machine 13. If the ADCs 9-11 are to perform analog-to-digital conversions on the voltage on a selected one of the input voltage terminals (with respect to the voltage on terminal VREF), then a multiplexer select control signal (a multibit digital control signal) is supplied by the control state machine 13 onto the select input leads of the analog multiplexer circuit, so that the analog multiplexer circuit will then couple the voltage from the selected input voltage terminal through the analog multiplexer circuit and onto the analog inputs of the ADCs 9-11. In this way, the ADCs can be made to perform analog-to-digital conversions on the voltage present on a selected one of the multiple input voltage terminals. Although such an analog multiplexer circuit is not illustrated for simplicity of explanation and clarity of illustration in FIG. 1, such an analog multiplexer circuit may be present in the signal path between the node of the AVIN terminal 6 and the common analog input node of the analog inputs of the ADCs 9-11.

Another embodiment of the radiation hardened (“rad-hard”) or radiation tolerant (“rad-tolerant”) analog-to-digital transducer integrated circuit is disclosed in U.S. patent application Ser. No. 18/759,812, titled “Processor Employing Instruction That Performs A Sum Of Two Closest Operation”, filed Jun. 29, 2024, by David A. Grant (the entire subject matter of which is incorporated herein by reference). In that embodiment, the integrated circuit includes three analog-to-digital converters (ADCs), each of them being a part of a corresponding slice portion of the integrated circuit. The integrated circuit has an analog sense voltage input terminal VFB. The first ADC performs an analog-to-digital conversion on the voltage present on the VFB input terminal, and the ADC output value is written into a first register. The second ADC performs an analog-to-digital conversion on the voltage present on the VFB input terminal, and the ADC output value is written into a second register. The third ADC performs an analog-to-digital conversion on the voltage present on the VFB input terminal, and the ADC output value is written into a third register. A digital processor of one of the slices executes a register sum of two closest (RSOC) instruction. Execution of the RSOC instruction causes the processor to read the three values, and to determine which two of the three values are the closest, and then to generate an output value that is sum of the two closest values. The sum is written into a register determined by the instruction. In the case of this embodiment of the integrated circuit, the digital processor is the FOTC circuit.

Although certain specific embodiments are described above for instructional purposes, the teachings of this patent document have general applicability and are not limited to the specific embodiments described above. The disclosed embodiments of circuitry that includes three ADCs and an FOTC circuit is usable outside the field of aerospace and in applications other than high radiation environments. Accordingly, various modifications, adaptations, and combinations of various features of the described embodiments can be practiced without departing from the scope of the invention as set forth in the claims.

What is claimed is:

1. An integrated circuit, comprising:
a first analog-to-digital converter (ADC) that outputs a first multi-bit digital value U;
a second analog-to-digital converter (ADC) that outputs a second multi-bit digital value M;
a third analog-to-digital converter (ADC) that outputs a third multi-bit digital value D; and
a function of two closest (FOTC) circuit that determines which two of the values U, M and D are the two numerically closest values, and that outputs a FOTC value taken from the group consisting of: one of the two numerically closest values, a sum of the two numerically closest values, and an average of the two numerically closest values.

2. The integrated circuit of claim 1, wherein the FOTC circuit comprises combinatorial digital logic elements, and wherein the FOTC circuit comprises no sequential digital logic element.

3. The integrated circuit of claim 1, further comprising:
a first integrated circuit terminal; and
a second integrated circuit terminal, wherein the value U is an analog-to-digital conversion value that is indicative of a voltage between the first and second integrated circuit terminals, wherein the value M is an analog-to-digital conversion value that is indicative of the voltage between the first and second integrated circuit terminals, and wherein the value D is an analog-to-digital conversion value that is indicative of the voltage between the first and second integrated circuit terminals.

4. The integrated circuit of claim 1, wherein the first ADC supplies the value U to the FOTC circuit in parallel via a first set of conductors, wherein the second ADC supplies the value M to the FOTC circuit in parallel via a second set of conductors, and wherein the third ADC supplies the value D to the FOTC circuit in parallel via a third set of conductors.

5. The integrated circuit of claim 1, further comprising:
a multi-terminal parallel digital output port, wherein the FOTC value is output from the integrated circuit via the multi-terminal parallel digital output port.

6. The integrated circuit of claim 1, further comprising:
a serial interface port, wherein the FOTC value is output from the integrated circuit via the serial interface port.

7. The integrated circuit of claim 1, wherein the integrated circuit is a packaged integrated circuit that includes an integrated circuit die and an integrated circuit package.

8. The integrated circuit of claim 1, wherein the integrated circuit is an integrated circuit die.

9. The integrated circuit of claim 1, wherein the FOTC circuit is an amount of field-programmable gate array (FPGA) circuitry.

10. The integrated circuit of claim 1, wherein the integrated circuit includes no processor that fetches and executes instructions.

11. The integrated circuit of claim 1, wherein if the numerical difference between a first pair of the U, M and D values is equal to the numerical difference between a second pair of the U, M and D values when the values U, M and D are all different values then the FOTC value output by the FOTC circuit is a value that is twice the middle value that is neither the largest of the U, M and D values nor the smallest of the U, M and D values.

12. The integrated circuit of claim 1, wherein if the numerical difference between a first pair of the U, M and D values is equal to the numerical difference between a second pair of the U, M and D values when the values U, M and D are all different values then the FOTC value output by the FOTC circuit is a value that is the sum of the largest of the U, M and D values and the smallest of the U, M and D values.

13. A circuit, comprising:
a first node;
a second node;
a first analog-to-digital converter (ADC) that outputs a first multi-bit digital value U, wherein the value U is an analog-to-digital conversion value that is indicative of a voltage between the first and second nodes;
a second analog-to-digital converter (ADC) that outputs a second multi-bit digital value M, wherein the value M is an analog-to-digital conversion value that is indicative of the voltage between the first and second nodes;
a third analog-to-digital converter (ADC) that outputs a third multi-bit digital value D, wherein the value D is an analog-to-digital conversion value that is indicative of the voltage between the first and second nodes; and
a function of two closest (FOTC) circuit that determines which two of the values U, M and D are the two numerically closest values, and that outputs a FOTC value taken from the group consisting of: one of the two numerically closest values, a sum of the two numerically closest values, and an average of the two numerically closest values.

14. The circuit of claim 13, wherein the FOTC circuit includes no digital processor that executes instructions.

15. A method comprising:
(a) using a first analog-to-digital converter (ADC) to generate a first multi-bit digital value U, wherein the value U is a value indicative of a voltage between a first node and a second node;
(b) using a second analog-to-digital converter (ADC) to generate a second multi-bit digital value M, wherein the value M is indicative of the voltage between the first node and the second node;
(c) using a third analog-to-digital converter (ADC) to generate a third multi-bit digital value D, wherein the value D is indicative of the voltage between the first node and the second node;
(d) determining which two of the values U, M and D are the two numerically closest values; and
(e) determining a function of two closest (FOTC) value, wherein the FOTC value is taken from the group consisting of: one of the two numerically closest values determined in (d), a sum of the two numerically closest values determined in (d), and an average of the two numerically closest values determined in (d), wherein neither (d) nor (e) is performed by a digital processor that executes instructions.

16. The method of claim 15, wherein (d) and (e) are performed by a function of two closest (FOTC) circuit, and wherein the FOTC circuit and the first, second and third ADCs are parts of an integrated circuit.

17. The method of claim 16, further comprising:
(f) outputting the FOTC value from the integrated circuit via a multi-terminal parallel digital output port.

18. The method of claim 16, further comprising:
(f) outputting the FOTC value from the integrated circuit via a serial interface port.

19. The method of claim 15, wherein the first node includes a first integrated circuit package terminal, and wherein the second node includes a second integrated circuit package terminal.

20. A method comprising:
(a) generating a first multi-bit digital value U using a first analog-to-digital converter (ADC), wherein the value U is a value indicative of a voltage between a first terminal of the integrated circuit and a second terminal of the integrated circuit, wherein the first ADC is a part of the integrated circuit;
(b) generating a second multi-bit digital value M using a second ADC, wherein the value M is a value indicative of the voltage between the first terminal and the second terminal, wherein the second ADC is a part of the integrated circuit;
(c) generating a third multi-bit digital value D using a third ADC, wherein the value D is a value indicative of the voltage between the first terminal and the second terminal, wherein the third ADC is a part of the integrated circuit;
(d) determining an FOTC value, wherein the FOTC value is a sum of the two numerically closest values of the values U, M and D, wherein the determining of (d) is performed by an FOTC circuit of the integrated circuit; and
(e) outputting the FOTC value from the integrated circuit.

21. The method of claim 20, wherein the FOTC value determined in (d) is the sum of the value M and the value D in a case in which the difference between the value D and the value U equals the difference between the value M and the value U, and wherein the FOTC value determined in (d) is the sum of the value D and the value U in a case in which the difference between the value D and the value M equals the difference between the value U and the value M, and wherein the FOTC value determined in (d) is the sum of the value U and the value M in the case in which the difference between the value U and the value D equals the difference between the value M and the value D.

22. The method of claim 20, wherein the FOTC circuit does not include a processor that executes instructions.
